(19) United States
(12) Patent Application Publication
(10) Pub. No.: US 2009/0249168 A1
(43) Pub. Date: Oct. 1, 2009

(54) STORAGE DEVICE

(75) Inventor: Hiroaki INOUE, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki (JP)

(21) Appl. No.: 12/409,976

(22) Filed: Mar. 24, 2009

(30) Foreign Application Priority Data
Mar. 27, 2008 (JP) 2008-083622

(51) Int. Cl. H03M 13/05; G06F 11/10

(52) U.S. Cl. 714/763; 714/E11.032

(57) ABSTRACT

A storage device includes: a storage medium; an auxiliary memory; and a controller for: determining an error correcting code length corresponding to an error rate of a data write area and/or an error correcting code write area of the storage medium; generating an error correcting code on the basis of the data and the determined error correcting code length; storing the generated error correcting code in the error correcting code write area and storing the data in the data write area; and storing a part of the error correcting code in the auxiliary memory if the generated error correcting code has a greater data length than that of the error correcting code write area, so that the part of the error correcting code overflowed from the error correcting code write area is stored in the auxiliary memory.

### CROSS-REFERENCE TO RELATED APPLICATION

This application is based upon and claims the benefit of priority of the prior Japanese Patent Application No. 2008-083622 filed on Mar. 27, 2008, the entire contents of which are incorporated herein by reference.

### FIELD

The embodiments discussed herein are related to a storage device for storing data.

### BACKGROUND

On the assumption that an error would occur when recorded data is read out, storage devices such as a magnetic disk drive perform error correction using an error correcting code. An error correcting code is generated when data is written into a storage medium of a storage device, and written into the storage medium together with the data.

As the length of an error correcting code (hereafter referred to as an “error correcting code length”) is increased, data having a higher error rate is error-corrected. However, if an error correcting code length is made larger than necessary, a storage area for data that should be originally stored is reduced. The “error rate” here refers to the rate of an error amount to a data amount.

Known as a method for optimizing an error correcting code length is a technology for setting the reliability of each of divided areas of a storage medium in multiple stages, selecting a storage area to which data is to be stored, from among the divided areas in accordance with the importance of the data, and storing the data in the selected storage area (see Japanese Patent Application Laid-open No. 2002-216426). Also known is a magnetic disk device including a magnetic disk in which sector data is written in a data area and a storage means that is different from the magnetic disk and into which a parity sector is written (see Japanese Patent Application Laid-open No. 2003-331527).

### SUMMARY

According to an aspect of the embodiment, a storage device includes: a storage medium including a data write area and an error correcting code write area; an auxiliary memory; and a controller for: determining an error correcting code length corresponding to an error rate of the data write area and/or the error correcting code write area where data and/or error correcting code are to be written into; generating an error correcting code on the basis of the data and the determined error correcting code length; storing the generated error correcting code in the error correcting code write area and storing the data in the data write area; and storing a part of the error correcting code in the auxiliary memory if the generated error correcting code has a greater data length than that of the error correcting code write area, so that the part of the error correcting code overflowed from the error correcting code write area is stored in the auxiliary memory.

The object and advantages of the embodiment will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 illustrates a diagram illustrating an overall configuration of a device;

FIG. 2 illustrates error correcting code determination table;

FIG. 3 is a flowchart of processes performed when determining an error correcting code length;

FIG. 4 is a flowchart of processes performed when determining an error correcting code length;

FIG. 5 is a diagram illustrating a configuration of an error correcting code length table;

FIG. 6 is a diagram illustrating a configuration of an error correcting code length table;

FIG. 7 is a diagram illustrating a configuration of an error correcting code length table;

FIG. 8 is a flowchart of processes performed when writing data; and

FIG. 9 is a flowchart of processes performed when reading out data.

### DESCRIPTION OF EMBODIMENTS

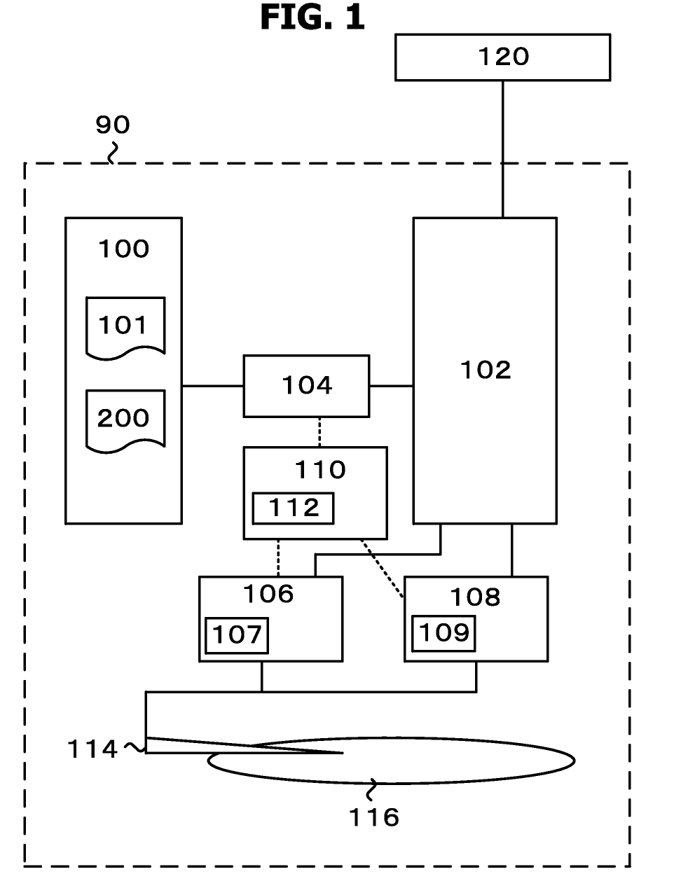

FIG. 1 is diagram illustrating an overall configuration of a hybrid hard drive as an example of a storage device 90. A hybrid hard drive refers to a storage device obtained by implementing a storage area different from a magnetic recording area in a typical magnetic recording unit. The storage device 90 includes a non-volatile memory 100, a volatile memory 102, a memory controller 104, a controller 110, an error correcting code generation unit 108, an error correction unit 106, a storage medium 116, and a magnetic head 114. The function of the error correcting code generation unit 108 and that of the error correction unit 106 to be described later may be parts of the function of the controller 110.

The storage medium 116 stores data, error correcting codes, and the like. Typically, the storage medium includes multiple disks, each of which is provided with the magnetic head 114. Tracks are obtained by dividing a disk into concentric storage areas. Sectors are obtained by dividing a track into equal parts radially. A cylinder is obtained by collecting tracks of an identical size by the number of the disks. Data stored in the storage medium is referred to by specifying a magnetic head number, a track number and a sector number. The storage areas preferably have equal lengths so that each storage area is easily accessed. This is because if the length of each storage area is variable, the control of access to each storage area is complicated.

Each storage area includes a data write area into which data is to be written and an error correcting code write area into which an error correcting code is to be written. The data write area and error correcting code write area each have a fixed length. The length of data to be written into the data write area is fixed; the length of an error correcting code to be written into the error correcting code write area is variable. If the length of the error correcting code is smaller than that of the error correcting code write area, the remaining area may be used as an area for storing data or the like.

Each storage area may include an area for storing CRC data used to detect an error. The length of CRC data is determined depending on the length of data. Since the length of data is fixed in this embodiment, the length of CRC data is also fixed.

The non-volatile memory 100 is one of storage areas and is a memory that is allowed to hold stored data even if the storage device is shut down. The non-volatile memory 100 stores an error correcting code length table 101 and a code length determination table 200. The non-volatile memory 100 serves as an auxiliary memory.

The volatile memory 102 temporarily holds data written by a higher-level device 120 thereinto or a readout command given by the higher-level device 120, or data to be read out to the higher-level device 120. If the storage device is shut down, data held by the volatile memory 102 is lost.

The memory controller 104 writes data into the non-volatile memory 100 or reads data therefrom.

The error correcting code generation unit 108 generates an error correcting code when data is written into the storage medium 116. The generated error correcting code is written into the storage medium 116 and non-volatile memory 100. The error correcting code generation unit 108 also has the function of generating CRC data.

A temporary memory area 109 holds data or the like written by the higher-level device 120. The error correcting code generation unit 108 generates an error correcting code data or CRC data on the basis of the data held by the temporary memory area 109. The error correcting code generation unit 108 may be implemented as a part of the function of the controller 110.

The error correction unit 106 performs error correction using ECC data when data is read out from the storage medium 116 to be described later. ECC data here refers to an error correcting code.

Also, the error correction unit 106 has the function of detecting an error using CRT (cyclic redundancy check) data. CRC data refers to data used to detect whether data read out from the storage medium 116 is different from data that has been written thereinto.

The temporary memory area 107 holds data, ECC data, CRC data, or the like read out from the storage medium 116. Using the held data, the error correction unit 106 performs an error correction process and an error detection process. The error correction unit 106 may be implemented as a part of the function of the controller 110.

The controller 110 controls the memory controller 104, error correction unit 106, error correcting code generation unit 108, and the like. A high-speed memory 112 is a memory implemented in the controller 110 and stores firmware or the like necessary when the controller 110 performs a process. The controller 110 is realized by a calculation unit such as an MPU (micro processing unit).

The magnetic head 114 is used when writing data in a predetermined position of the storage medium 116 or reading out data from a predetermined position.

The higher-level device 120 is a host system for giving a data write command or a data read command to the storage device 90. The higher-level device 120 lies outside the storage device 90.

When the storage device 90 receives a write command sent from the higher-level device 120, the controller 110 identifies an address in a storage medium at which data is to be written, on the basis of address information included in the write command. The write command sent from the higher-level device 120 includes information such as information indicating that the command is a write command, information indicating the address of a destination to which the data is to be written, and information indicating the length of the data. The controller 110 refers to an error correcting code length corresponding to the address of the write destination of the data in the error correcting code length table and notifies the error correcting code generation unit 108 of the error correcting code length. The error correcting code generation unit 108 generates an error correcting code for the data on the basis of the error correcting code length. The controller 110 stores the data in a data write area of a storage area of the storage medium, as well as stores the error correcting code in an error correcting code write area of the storage area. The data write area and error correcting code write area each have a fixed length. If the error correcting code exceeds the error correcting code write area, the controller 110 stores a part of the error correcting code exceeding the error correcting code write area in the non-volatile memory 100.

Since each storage area of the storage medium 116 has a fixed length, the storage medium 116 is allowed to store an error correcting code having an optimum length in each storage area without complicating the control of access to the storage medium 116. Also, the storage capacity of the non-volatile memory 100 for the error correcting code length table 101 is reduced.

When the storage device 90 receives a data read command from the higher-level device 120, the controller 110 reads out parts of data and an error correcting code corresponding to the respective fixed lengths thereof, from a storage area of the storage medium 116 corresponding to the read command and sends the read-out parts to the error correction unit 106. Here, the read command includes information such as information indicating the address of a source from which data is to be read and information indicating the length of the data. The controller 110 reads out a part of the error correcting code corresponding to a variable length thereof from the error correcting code length table 101 on the basis of the read source address information and sends the variable-length part to the error correction unit 106. The error correction unit 106 performs error correction on the data using the received error correcting code. The control 110 sends the resultant data to the higher-level device 120. That is, after the read command is received, the data is corrected using the optimum error correcting code and sent to the higher-level device 120.

As described above, the controller 110 writes an error correcting code into the storage medium 116 and error correcting code length table 101 in such a manner that the error correcting code is divided. In this case, the error correction unit 106 reads out a part of the error correcting code stored in the storage medium 116 and the remaining part of the error correcting code stored in the error correcting code length table 101 and combines these parts. Using the resultant error correcting code, the error correction unit 106 performs error correction on the data. That is, after the read command is received, the data is corrected using the optimum error correcting code and then sent to the higher-level device 120.

Error correcting codes are written into the corresponding sectors of the storage medium 116 together with data. For this reason, the error correcting code length of each sector must be determined before data is written into the storage medium 116. The address in the storage medium 116 at which data is to be written may be determined on a sector-by-sector basis. Here, a “sector” is one of categories of storage areas in the storage medium 116.

The error correcting code length is determined by writing data into each sector of the storage medium 116 and reading out the data from each sector and comparing the written data and the read-out data so as to obtain an error rate for each sector. In the following description, it is assumed that the error rate is the number of error bits with respect to the length of written data. The number of error bits refers to the number of error bits in a case where the written data is different from the read data.

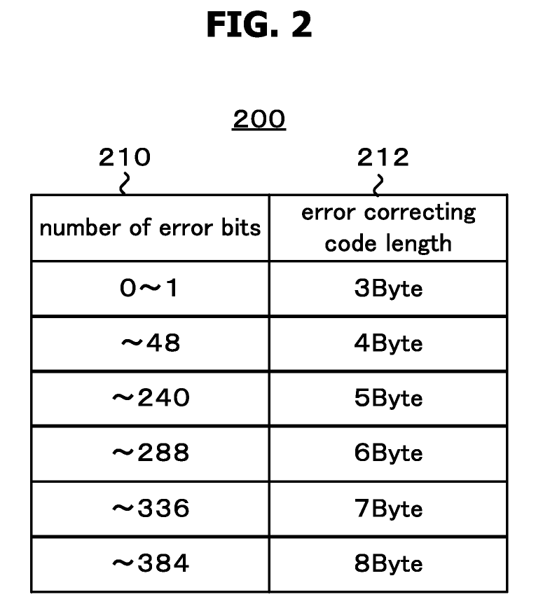

FIG. 2 is a code length determination table 200 used to determine an error correcting code length necessary to perform error correction on data having a certain number of error bits. The code length determination table 200 includes an error bit number column 210 and an error correcting code length column 212.

The code length determination table 200 is stored in a non-volatile area such as the high-speed memory 112 or non-volatile memory 100. On the basis of the code length determination table 200, the controller 110 determines an error correcting code length corresponding to the error bit number of data stored in each sector of the storage medium 116. Also, the minimum value of an error correcting code length may be determined so that even if the error bit number of data is zero as illustrated in FIG. 2, minimum data correction is performed. Further, if the error bit number of data in a sector exceeds the maximum value shown in the code length determination table 200, this sector may be handled as an unavailable sector. Also, in this embodiment, the data length is fixed and the error correcting code length is variable; therefore, the error correcting code length may be determined in accordance with the error rate that is the rate of the error bit number to the data length.

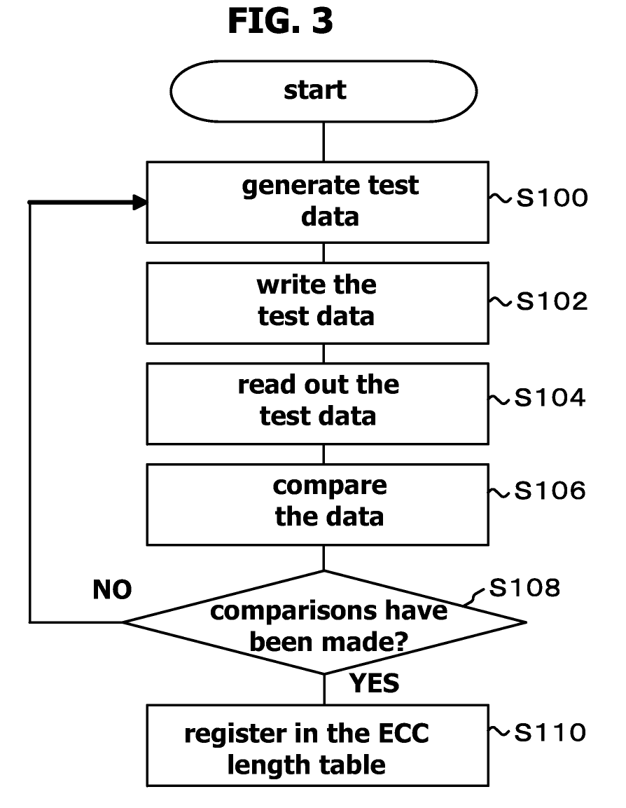

FIG. 3 is a first flowchart of processes performed when determining an error correcting code length.

The controller 110 generates test data to be used to obtain an error bit number (S100), writes the generated test data into one sector of the storage medium 116 (S102), reads out the test data written in the sector (S104), and compares the written data and read-out data (S106). In step 100, several pieces of test data are generated. If there remain pieces of test data with respect to which no comparison has been made (NO in S108), the remaining pieces of data are subjected to the same process. If comparisons have been made with respect to all pieces of test data (YES in S108), an error correcting code length corresponding to test data including the largest number of error bits have been found is registered in the error correcting code length table (S110). The above-mentioned processes are performed for each sector and the results are registered in the error correcting code length table. “ECC LENGTH” in step 110 of FIG. 3 refers to an error correcting code length.

The reason why multiple pieces of test data are prepared is that there may be differences in the probability of failure of data matching among the pieces of test data. The controller 110 may generate any type of test data. Also, the temperature condition may be changed when writing or reading out test data, and the error correcting code length may be determined in consideration of the influence of the temperature on the storage medium 116 or magnetic head 114.

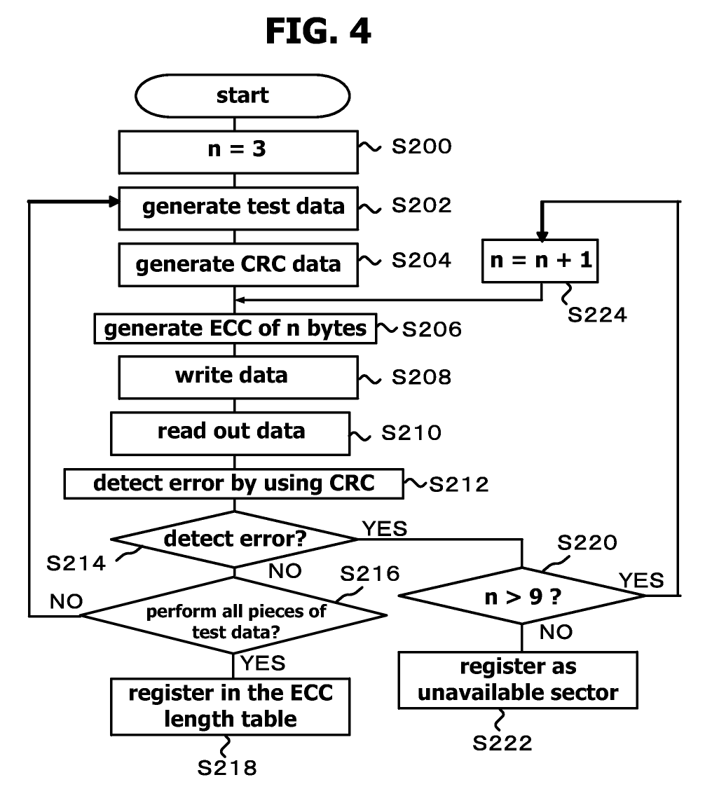

FIG. 4 is a second flowchart of processes performed when determining an error correcting code length.

The controller 110 writes data into each sector of the storage medium 116 and reads out the data therefrom while gradually increasing the error correcting code length with respect to the data having a fixed length. If data has been read out correctly from a sector, the controller 110 registers an error correcting code length used at that time as the error correcting code length of this sector in the error correcting code length table.

The controller 110 sets an error correcting code length n of a sector to be processed, to three as the initial value (S200). The controller 110 generates test data (S202), and generates CRC data corresponding to the generated test data (S204) and instructs the error correcting code generation unit 108 to generate an error correcting code of n bytes (S206).

The controller 110 writes data into a sector to be processed (S208) and then reads out the written data (S210). The controller 110 instructs the error correction unit 106 to perform error correction on the read-out data using an error correcting code and then perform an error detection process on the error-corrected data using CRC data (S212). If it is determined that the data has an error (YES in S214) and if n is less than nine (YES in S220), n is increased by one (S224) and an error detection process is performed again.

If the data has no error (NO in S214) and if the above-mentioned processes have been performed with respect to all pieces of test data (YES in S216), the controller 110 registers the current n value as the error correcting code length of this sector in the error correcting code length table (S218). If the above-mentioned processes have not been performed with respect to all pieces of test data (NO in S216), test data is generated again (S202).

If the error correcting code length n is equal to or more than nine (NO in S220), the controller 110 registers this sector as an unavailable sector in the error correcting code length table to be described later (S222). For example, a character string instead of a numerical value is registered as the error correcting code length of this sector in the error correcting code length table. Thus, before data is actually written into the sector, that is, at a time when a sector into which the data is to be written is specified by the higher-level device 120, the controller 110 determines that the sector is unavailable.

The reason why multiple pieces of test data are prepared is that there may be differences in the probability of failure of data matching among pieces of test data. Also, the temperature condition may be changed when writing or reading out test data, and the error correcting code length may be determined in consideration of the influence of the temperature on the storage medium 116 or magnetic head 114.

In FIG. 4, the error correcting code length may be determined for each track, each head, or each cylinder rather than for each sector. By determining the error correcting code length for storage areas larger than sectors, the load imposed on the controller 110 when writing error correcting code lengths into the error correcting code length table to be described later is reduced. A storage area including multiple sectors, such as a track, is called a group.

The storage medium 116 typically includes multiple disks. Each disk is provided with the magnetic head 114. Tracks are obtained by dividing a disk into concentric areas. Sectors are obtained by dividing a track into equal parts radially. A cylinder is obtained by collecting tracks of an identical size by the number of the disks. As is understood from the above description, the storage areas of the storage medium 116 form a hierarchical structure. Each magnetic head, each track, and each sector are assigned a unique head number, a unique track number, and a unique sector number, respectively. Thus, an arbitrary sector of the storage medium 116 is specified using a head number, a track number, and a sector number. Also, an arbitrary sector may be specified using only a sector number by assigning serial numbers to all sectors existing in the storage medium 116.

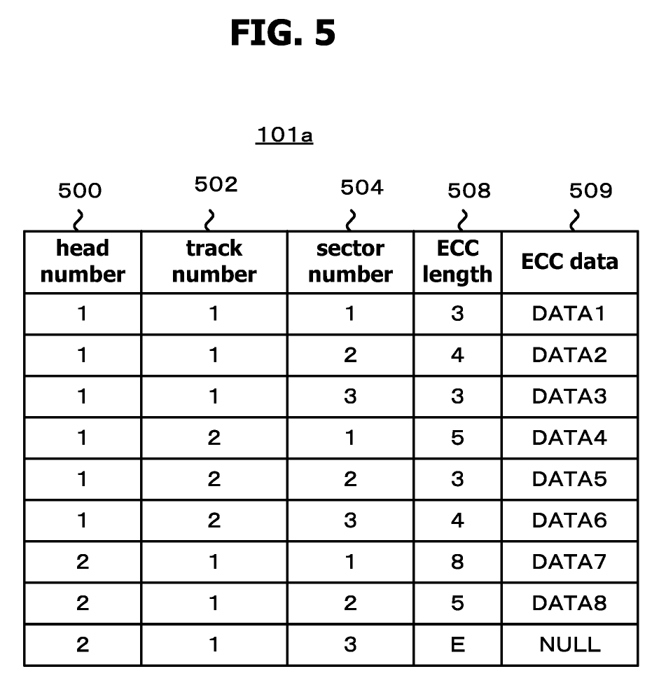

FIG. 5 is a diagram illustrating a configuration of the error correcting code length table 101a in a case where an error correcting code length is determined for each sector.

A column 500 includes head numbers. Head number “1” is stored in each of the first to sixth rows of the column 500 and head number “2” is stored in each of the seventh to ninth rows of the column 500 and a head number “2” is stored in the seventh to ninth rows. Since each disk is provided with a head in the storage medium 116, it is understood from the error correcting code length table 101a that the storage medium 116 includes at least two disks.

A column 502 includes track numbers. Track number “1” corresponding to head number “1” is stored in each of the first to third rows of the column 502. Track number “2” corresponding to head number “1” is stored in each of the fourth to sixth rows of the column 502. Track number “1” corresponding to head number “2” is stored in each of the seventh to ninth rows of the column 502. Since tracks are concentric areas of a disk, it is understood from the error correcting code length table 101a that in the storage medium 116, one disk includes at least two track areas.

A column 504 includes sector numbers. Sector numbers “1,” “2,” and “3” corresponding to head number “1” and track number “1” are stored in the first to third rows of the column 504, sector numbers “1,” “2,” and “3” corresponding to head number “1” and track number “2” are stored in the fourth to sixth rows thereof, and sector numbers “1,” “2,” and “3” corresponding to head number “2” and track number “1” are stored in the seventh to ninth rows thereof. Since sectors are obtained by dividing each track in equal parts radially, it is understood from the error correcting code length table 101a that in the storage medium 116, one track includes at least three sector areas.

A column 508 includes ECC lengths assigned to sectors. For example, an ECC length necessary to perform error correction on data in a storage area corresponding to head number “1,” track number “1,” and sector number “1” is 3. On the other hand, an ECC length necessary to perform error correction on data in a storage area corresponding to head number “2,” track number “1,” and sector number “3” is “E.” This means that the storage area corresponding to head number “2,” track number “1,” and sector number “3” is an unwritable area. The ECC length for each storage area is obtained through the processes illustrated in FIG. 3 or 4 and stored in the column 508.

A column 509 includes parts of pieces of ECC data generated by the error correcting code generation unit 108 using the ECC lengths assigned to the sectors and the written data. The pieces of ECC data generated by the error correcting code generation unit 108 are each stored in the storage medium 116 and column 509 of the error correcting code length table 101a in such a manner that each error correcting code is divided, as will be described later. ECC data corresponding to head number “1,” track number “1,” and sector number “3” is “NULL.” This means that this sector is an unwritable area and thus includes no ECC data.

Using the error correcting code length table 101a, the controller 110 individually sets an ECC length and ECC data for all sectors of the storage medium 116. Here, ECC data means an error correcting code and an ECC length means an error correcting code length.

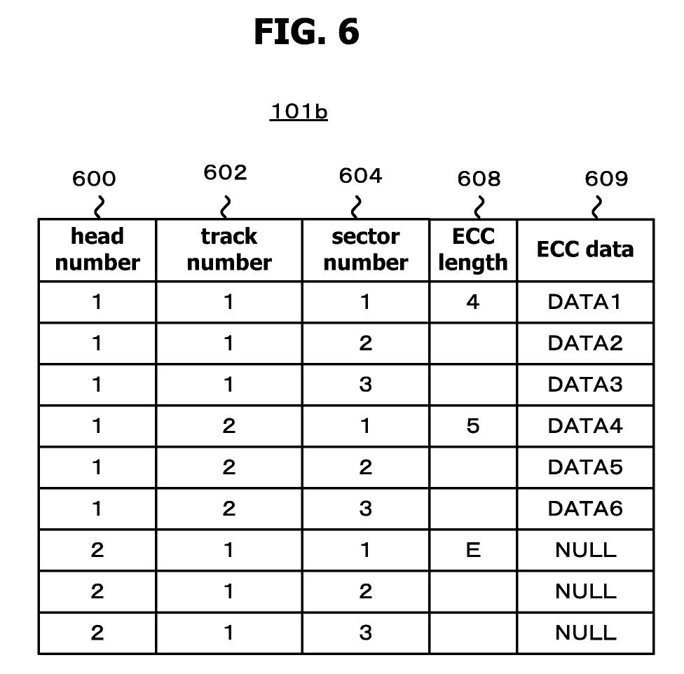

FIG. 6 is a diagram illustrating a configuration of an error correcting code length table 101b in a case where an error correcting code length is determined for each track.

A column 600 includes head numbers. Specifically, the column 600 includes head numbers “1” and “2.” Since each disk is provided with a head in the storage medium 116, it is understood from the error correcting code length table 101b that the storage medium 116 includes at least two disks.

A column 602 includes track numbers. Specifically, the column 602 includes track numbers “1” and “2.” Tracks are concentric areas of a disk and one disk includes two track areas in the storage medium 116 corresponding to the error correcting code length table 101b.

A column 604 includes sector numbers. Specifically, the column 600 includes sector numbers “1,” “2,” and “3.” Since sectors are obtained by dividing one track into equal parts radially, it is understood from the error correcting code length table 101b that in the storage medium 116, one track includes three sector areas.

A column 608 includes ECC lengths assigned to tracks. For example, an ECC length necessary to perform error correction on data in a storage area corresponding to head number “1” and track number “1” is 4 bytes regardless of what the sector number stored in the column 604 is. The ECC length of each track is determined, for example, in the following manner. First, the controller 110 obtains the respective ECC lengths of the sectors “1,” “2,” and “3” corresponding to head number “1” and track number “1” through the processes illustrated in FIG. 3 or 4. Then, if the largest value of the obtained ECC lengths is 4 bytes, the controller 110 sets 4 bytes for each of the ECC lengths of the sectors corresponding to head number “1” and track number “1.” In this way, the ECC lengths of the sectors of each track are optimized.

On the other hand, the respective ECC lengths of the sectors corresponding to head number “2” and track number “1” are “E.” This means that the sectors corresponding to head number “2” and track number “1” are unwritable areas. Even if only one of the sectors corresponding to head number “2” and track number “1” is an unwritable area, other sectors in the same track are also preferably handled as unwritable areas. Since sectors of an identical track have equal ECC lengths, the ECC length may be stored in only a row corresponding to the number of the top sector of each track. For example, ECC lengths may be stored in only the first, fourth, and seventh rows of the column 608. Thus, storage areas for storing an ECC length are reduced.

A column 609 includes parts of pieces of ECC data generated by the error correcting code generation unit 108 using the ECC lengths assigned to the sectors and the written data. The pieces of ECC data generated by the error correcting code generation unit 108 are stored in storage areas of the storage medium 116 and the column 609 of the error correcting code length table 101b in such a manner that the pieces of ECC data are each divided.

The error correcting code length may be determined for each head or each cylinder rather than for each track. If error correcting code lengths are determined for storage areas at a level higher than that of sectors, the controller 110 need not set different error correcting code lengths for sectors. This allows the controller 110 to perform an error correcting code generation process in a simplified way. The reason why such simplification is realized will be described later.

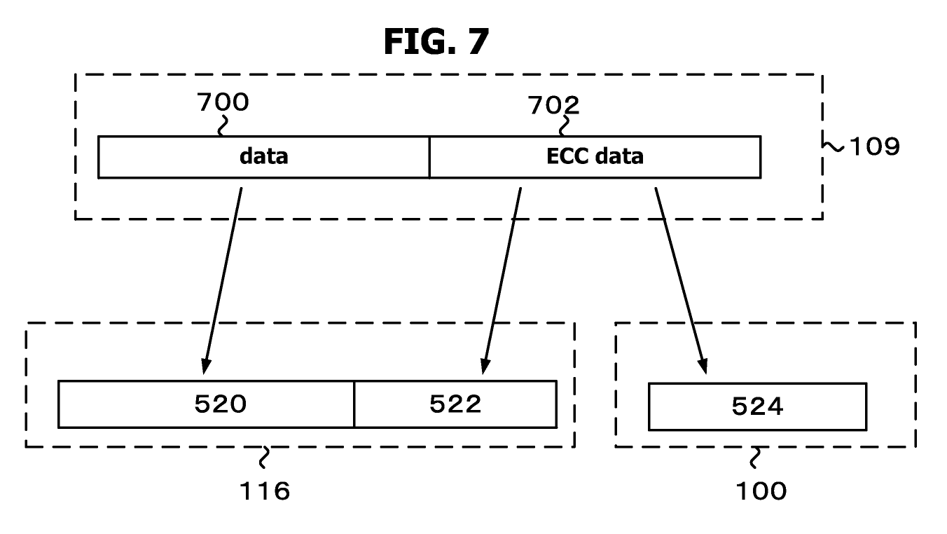

FIG. 7 is a diagram illustrating a data configuration in a case where a part of ECC data having a predetermined fixed length is stored in the storage medium 116 and the remaining part of the ECC data having a length exceeding the fixed length is stored in the non-volatile memory 100. Here, it is assumed that written data 700 and ECC data 702 corresponding to the data 700 is held by the temporary memory area 109 of the error correcting code generation unit 108. Also, the part of the ECC data stored in the storage medium 116 will be referred to as a “fixed part” and the remaining part of the ECC data stored in the non-volatile memory 100 will be referred to as a “variable part”.

The storage areas of the storage medium 116 each include a data write area 520 for storing data and an error correcting code write area 522 for storing ECC data having a predetermined length. A storage area 524 of the non-volatile memory 100 stores the remaining part of ECC data that has not been written into the error correcting code write area 522. Here, the storage area 524 is the column 509 of the error correcting code length table 101a of the non-volatile memory 100 or the column 609 of the error correcting code length table 101b. The data 700 held by the temporary memory area 109 is stored in the data write area 520. A part having a length writable into the error correcting code write area 522, of the ECC data 702 held by the temporary memory area 109 is stored in the error correcting code write area 522.

The ECC data 702 may be stored in the error correcting code write area 522 sequentially from the top bit thereof and the remaining bits of the ECC data 702 may be stored in the storage area 524 of the error correcting code length table 101.

Even if no error occurs in a storage area of the storage medium 116 when an ECC length is determined for the storage area, an error may occur when the storage area is used later. In this case, if required minimum ECC data is previously stored in such a storage area, the reliability of data in the storage area is improved. Also, by fixing the length of the error correcting code write area 522 included in the storage medium 116, the control of access to the storage medium 116 is prevented from being complicated. Further, by storing a part of ECC data in the error correcting code write area 522 in the storage medium 116, the storage capacity for the remaining part of the ECC data of the non-volatile memory 100 is reduced.

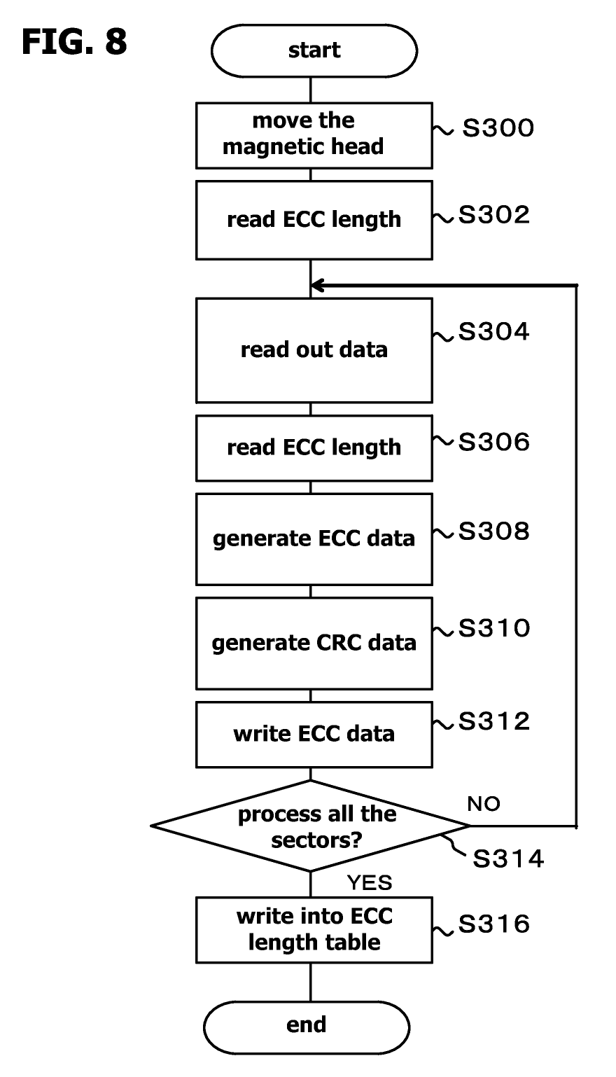

FIG. 8 illustrates a flow of processes for writing data into the storage medium 116 and processes for writing, into the non-volatile memory 100, ECC data corresponding to an area where the data is written. Hereafter, the processes for writing the data and processes for writing the ECC data will be described using a case where data is to be written into the sectors described in the first to third rows of the ECC length table 101a illustrated in FIG. 5 or into the sectors described in the first to third rows of the ECC length table 101b illustrated in FIG. 6.

Before writing data into the storage medium 116, the higher-level device 120 issues a write command to specify a sector that is a storage area of the storage medium 116. Therefore, if data is to be written into the sectors described in the first to third rows of the ECC length table 101a or into the sectors described in the first to third rows of the ECC length table 101b and if the sector corresponding to head number “1,” track number “1,” and sector number “1” is specified, the controller 110 moves the magnetic head 114 to the sector in preparation for writing of the data into the storage medium (S300).

If an ECC length is written into the non-volatile memory 100 on a sector-by-sector basis in a case where the write speed of the non-volatile memory 100 storing the ECC length table 101a or ECC length table 101b is slow, processes with respect to subsequent sectors can be delayed. Therefore, in order to efficiently perform processes for writing ECC data, the controller 110 reads out or writes ECC lengths from or into the ECC length table 101a or ECC length table 101b on a track-by-track basis. Therefore, if data is to be written into the sectors in the first to third rows of the column 508, the controller 110 reads out the ECC lengths in the first to third rows of the column 508 from the non-volatile memory 100 and stores the read-out ECC lengths in the volatile memory 102. On the other hand, if data is to be written into the sectors in the first to third rows of the ECC length table 101b, the controller 110 reads out only the ECC length of the sector “1” that is the top sector of the track “1” since the ECC lengths are identical to one another in each track. Then, the controller 110 stores the read ECC length in the volatile memory 102 (S302).

If the storage device 90 becomes writable receiving the write command from the higher-level device 120, the controller 110 sends a write permission signal to the higher-level device 120. Upon receipt of the write permission signal, the higher-level device 120 sends the data to the storage device 90. The controller 110 writes the data sent from the higher-level device 120 into the volatile memory 102. Subsequently, the controller 110 sends the data, with respect to which ECC data is to be generated, to the error correcting code generation unit 108. Specifically, if data is to be written into the sectors in the first to third rows of the ECC length table 101a or the sectors in the first to third rows of the ECC length table 101b, the controller 110 reads out the data, which is to be written into the sector corresponding to head number “1,” track number “1,” and the sector number “1,” from the volatile memory 102 and writes the read-out data into the temporary memory area 109 (S304) of the error correcting code generation unit 108.

The controller 110 reads out an ECC length corresponding to the data written into the temporary memory area 109, from the volatile memory 102. If data is to be written into the sectors in the first to third rows of the ECC length table 101a, the controller 110 reads out an ECC length of 3 bytes corresponding to the sector corresponding to head number “1”, track number “1”, and sector number “1” from the volatile memory 102 and writes the read-out ECC length into the temporary memory area 109. Since the sectors have different ECC lengths, the controller 110 must read out an ECC length from the volatile memory 102 each time the sector into which data is to be written is changed to another sector and must write the read-out ECC length into the temporary memory area 109.

On the other hand, if data is to be written into the sectors in the first to third rows of the ECC length table 101b, the sectors of an identical track have equal ECC lengths. Therefore, even if the sector to which data is to be written is changed to another sector, the controller 110 need not read out an ECC length again from the volatile memory 102 or write the ECC length into the temporary memory area 109 if the other sector is included in the same track. Therefore, if an ECC length of 4 bytes corresponding to the sector corresponding to head number “1”, track number “1” is written once, and sector number “1”, processes are advanced without having to write an ECC length corresponding to sector number “2” in the same track again while regarding the ECC length as 4 bytes (S306).

The error correcting code generation unit 108 generates ECC data having the ECC length written into the temporary memory area 109, with respect to the data written into the temporary memory area 109. The process for generating ECC data varies depending on ECC lengths. The error correcting code generation unit 108 writes the generated ECC data into the temporary memory area 109. For example, if data is to be written into the sectors in the first to third rows of the ECC length table 101a, the error correcting code generation unit 108 generates, with respect to the written data, ECC data having the ECC length of 3 bytes corresponding to the sector corresponding to head number “1”, track number “1”, and sector number “1” and writes the generated ECC data into the temporary memory area 109 (S308).

Also, the error correcting code generation unit 108 generates CRC data corresponding to the written data and writes the generated CRC data into the temporary memory area 109 (S310).

The controller 110 writes the data and CRC data written into the temporary memory area 109 into the storage medium 116. For example, if data is to be written into the sectors in the first to third rows of the ECC length table 101a, the controller 110 writes the data and CRC data written into the temporary memory area 109, into the sector corresponding to head number “1”, track number “1”, and sector number “1.”

The controller 110 compares the preset size of the error correcting code write area 522 and the length of the generated ECC data held in the temporary memory area 109. If the ECC length is equal to or smaller than the size, the ECC data is written into the storage medium 116. For example, if the size of the error correcting code write area 522 is 3 bytes and if data is to be written into the sector in the first row of the ECC length table 101a, the controller 110 writes the ECC data having a length of 3 bytes into the error correcting code write area 522 of the sector corresponding to head number “1”, track number “1”, and sector number “1.”

On the other hand, if the ECC length is larger than the size of the error correcting code write area 522, the controller 110 divides the generated ECC data held in the temporary memory area 109 into a fixed part having a length of bytes equal to the size of the error correcting code write area 522 and a variable part that is the remaining part. For example, if the size of the error correcting code write area 522 is 3 bytes and data is to be written into the sector in the second row of the ECC length table 101a, the controller 110 divides the generated ECC data having a length of 4 bytes into a fixed part having a length of 3 bytes and a variable part having a length of 1 byte. The controller 110 writes the fixed part into the error correcting code write area 522 of the sector corresponding to head number “1”, track number “1”, and sector number “2.” Also, the controller 110 writes the variable part as a variable part corresponding to head number “1”, track number “1”, and sector number “2,” into the non-volatile memory 100 (S312).

If the above-mentioned processes have been performed on all sectors of the same track, the controller 110 writes the variable parts corresponding to these sectors into the error correcting code length table 101 in the non-volatile memory 100. If writing of data into the data write area 520 and writing of a fixed part into the error correcting code write area 522 has been performed with respect to all the sectors in the first to third rows of the ECC length table 101a or all the sectors in the first to third rows of the ECC length table 101b (YES in S314), the controller 110 writes the variable parts corresponding to the sectors written in the volatile memory 102 into the column 509 or column 609 of the ECC length table 101a or 101b that is the storage area 524 of the non-volatile memory 100 (S316). Thus, the write process is completed. In this case, by performing write processes on the non-volatile memory 100 on a track-by-track basis, the write frequency is reduced so that the write efficiency is improved with respect to the non-volatile memory 100, whose write speed is slow. If data has been written into not all the sectors of the track (NO in S304), data is continuously written into the remaining sectors.

The length of CRC data is determined depending on the length of the written data. Therefore, if the written data has a fixed length, CRC data also has a fixed length. Therefore, if CRC data is written into a storage area of the storage medium 116 together with the data, the storage area has a fixed length. This prevents complication of the readout control of data from the storage medium 116. Also, CRC data may be written into the non-volatile memory 100 together with a variable part of ECC data. By storing CRC data in an area other than the storage medium 116, the reliability of the CRC data is improved.

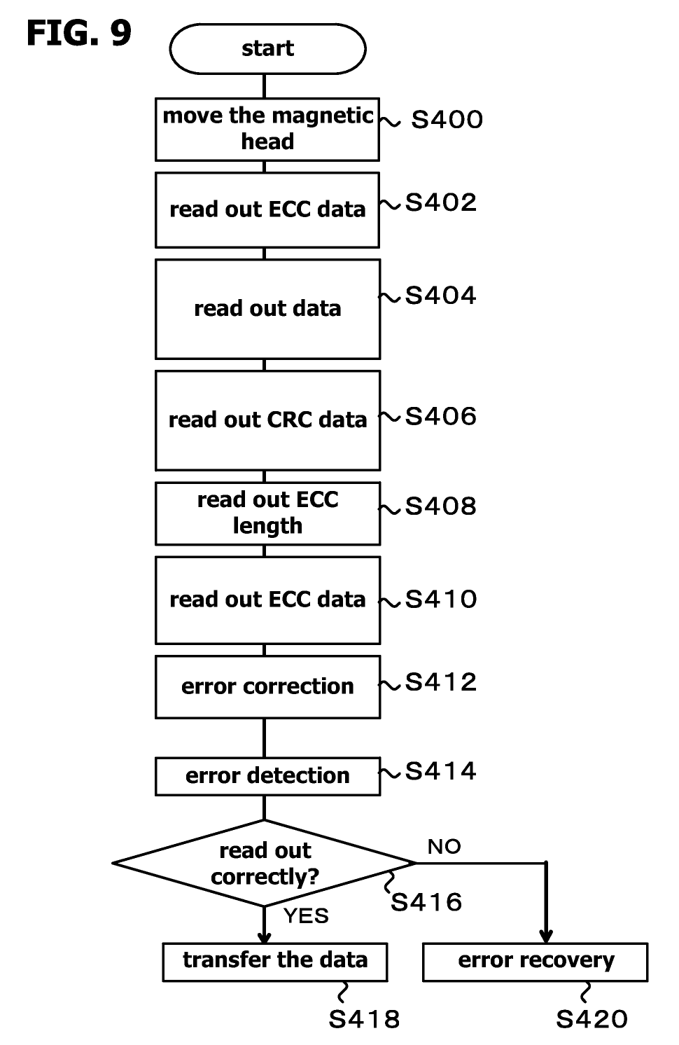

FIG. 9 illustrates a flow of data read processes in a case where ECC data corresponding to data stored in the storage medium 116 is stored in the non-volatile memory 100.

Upon receipt of a data read command from the higher-level device 120, the controller 110 specifies a track in which data to be read is stored, on the basis of address information included in the read command and moves the magnetic head 114 (S400).

The controller 110 reads out the remaining bits of ECC data corresponding to this track and exceeding the size of the error correcting code write area 522 from the error correcting code length table 101 stored in the non-volatile memory 100, and loads the read-out remaining bits into the volatile memory 102 (S402). By collectively reading data stored in multiple sectors of one track in this way, the frequency of access to the non-volatile memory 100 is reduced so that the readout efficiency is improved.

Subsequently, the controller 110 reads out data stored in the sectors of the track and a part of ECC data written into the error correcting code write area 522 sequentially from the top bit, via the magnetic head 114 and loads the read-out data into a temporary memory area 107 implemented in the error correction unit 106 (S404).

Also, the controller 110 reads out CRC data corresponding to the sectors via the magnetic head 114 and loads the read CRC data into the temporary memory area 107 (S406).

Subsequently, the controller 110 reads out the ECC length of each sector (S408). Since an error correction process using ECC data varies depending on ECC lengths, an ECC length is required when the error correction unit 106 performs error correction process. Also, the controller 110 reads out the remaining bits of ECC data corresponding to each sector and exceeding the size of the error correcting code write area 522, from the volatile memory 102 and then loads the read-out remaining bits into the temporary memory area 107 (S410). Then, the error correction unit 106 combines the part of the ECC data and the remaining bits of the ECC data loaded into the temporary memory area 107.

The error correction unit 106 performs error correction on the data read out from the storage medium 116 using the combined ECC data (S412). Also, the error correction unit 106 performs error detection on the error-corrected data using CRC data (S414).

If the controller 110 determines that the data has been read out correctly, on the basis of the error correction performed by the error correction unit 106 (YES in S416), the controller 110 transfers the data to the higher-level device 120 via the volatile memory 102 (S418). In contrast, if the controller 110 determines that the data has not been read out correctly (NO in S416), the controller 110 performs an error recovery process (S420). Specifically, the controller 110 performs an error recovery process, for example, by performing the above-mentioned read process on the same sector several times or shifting the position of the magnetic head 114 through which data passes when the data is read out from the storage medium 116. In this way, the data read out in accordance with the readout command is corrected using the optimum error correcting code and transmitted to the higher-order device.

The method for storing data in a storage device shown in the above-mentioned embodiment may be performed using a device accessible to a storage medium. Among devices accessible to a storage medium are not only a higher-level device but also a test device, a production facility, and a device disposed on a network. Among storage media are not only a magnetic disk but also transportable storage media such as a non-volatile memory, a compact disc-read-only memory (CD-ROM), a flexible disk, a digital versatile disc (DVD), a magneto-optical disk, and an IC card and storage media disposed on a network.

What is claimed is:

1. A storage device comprising:
a storage medium including a data write area and an error correcting code write area;
an auxiliary memory; and
a controller for:
determining an error correcting code length corresponding to an error rate of the data write area and/or the error correcting code write area where data and/or error correcting code are to be written into;
generating an error correcting code on the basis of the data and the determined error correcting code length;
storing the generated error correcting code in the error correcting code write area and storing the data in the data write area; and
storing a part of the error correcting code in the auxiliary memory if the generated error correcting code has a greater data length than that of the error correcting code write area, so that the part of the error correcting code overflowed from the error correcting code write area is stored in the auxiliary memory.

2. The storage device of claim 1, wherein the auxiliary memory stores, as a error correcting code length table, the storage areas for storing data, error correcting code lengths corresponding to the storage areas, and error correcting codes generated on the basis of the data and the error correcting code lengths.

3. The storage device of claim 2, wherein a storage area having the error bit number less than a predetermined value among the storage areas is set as an unavailable area in the error correcting code length table.

4. The storage device of claim 1, wherein on the basis of an error bit number, the error bit number indicating the number of error bits in a case where test data that has yet to be stored in the storage media is different from the test data that has been stored in the storage media, the controller determines an error correcting code length used when performing error correction on the test data.

5. The storage device of claim 1, wherein the storage medium includes one or more groups, each of the one or more groups grouping the storage areas, and the controller sets identical error correcting code lengths for the storage areas belonging to each of the one or more groups.

6. A method for storing data in a storage device, the storage device including: a storage medium including a data write area and an error correcting code write area; and an auxiliary memory, the method comprising:
determining an error correcting code length corresponding to an error rate of the data write area and/or the error correcting code write area where data and/or error correcting code are to be written into;
generating an error correcting code on the basis of the data and the determined error correcting code length;
storing the generated error correcting code in the error correcting code write area and storing the data in the data write area; and
storing a part of the error correcting code in the auxiliary memory if the generated error correcting code has a greater data length than that of the error correcting code write area, so that the part of the error correcting code overflowed from the error correcting code write area is stored in the auxiliary memory.

7. The method for storing data in a storage device of claim 6, wherein the auxiliary memory stores, as a error correcting code length table, the storage areas for storing data, error correcting code lengths corresponding to the storage areas, and error correcting codes generated on the basis of the data and the error correcting code lengths.
